(19) United States
(12) Patent Application Publication
(10) Pub. No.: US 2026/0372130 A1
(43) Pub. Date: Nov. 19, 2026

(54) OPTICAL PACKAGE STRUCTURE AND MANUFACTURING METHOD THEREOF

(71) Applicant: SILICONWARE PRECISION INDUSTRIES CO., LTD., Taichung City (TW)

(72) Inventors: Chia-Pu LIANG, Taichung City (TW); Pei-Hsuan KE, Taichung City (TW); Jun-Yan LI, Taichung City (TW); Chia-Hsi HSIEH, Taichung City (TW)

(73) Assignee: SILICONWARE PRECISION INDUSTRIES CO., LTD., Taichung City (TW)

(21) Appl. No.: 19/419,385

(22) Filed: Dec. 15, 2025

(30) Foreign Application Priority Data
May 16, 2025 (TW) 114118507

(51) Int. Cl. H10W 70/63; G02B 6/13; H10W 70/05

(52) U.S. Cl. CPC H10W 70/63; G02B 6/13; H10W 70/095

(57) ABSTRACT

An optical package structure and a manufacturing method thereof are provided. At least one optical element is disposed on a substrate, and an interposer having a plurality of conductive vias is provided to connect an electronic element and at least one semiconductor element to the interposer. The electronic element and the semiconductor element are electrically connected to the plurality of conductive vias, the interposer is placed on the substrate and the optical element, and the substrate and the optical element are electrically connected to the plurality of conductive vias, so that the optical element, the semiconductor element, and the electronic element can be electrically connected to each other via the plurality of conductive vias of the interposer, thereby shortening the path of electrical transmission.

### BACKGROUND

### 1. Technical Field

The present disclosure relates to a semiconductor package structure, and more particularly, to an optical package structure having at least one optical element and a manufacturing method thereof.

### 2. Description of Related Art

With the vigorous development of the electronics industry, electronic products are gradually moving towards multi-functionality and high performance. At present, the application of the fifth generation (5G) communication technology has expanded to the fields of Internet of Things (IoT), Industrial Internet of Things (IIoT), cloud computing, artificial intelligence (AI), autonomous vehicles, and medical care. As the application level expands, a large amount of data will be generated and needs to be efficiently transmitted, processed, and stored. In particular, the demand for data transfer is surging, prompting the industry to adopt “light” instead of “electricity” as the data-transmission medium to boost capacity, efficiency, and range while reducing power consumption. In this context, co-packaged optics has emerged as a development trend in future semiconductor and packaging technologies.

Please refer to FIG. 1, which is a cross-sectional schematic view of a conventional co-packaged optical device 1. An optoelectronic module 11 is disposed on a circuit board 10. The optoelectronic module 11 includes a semiconductor chip 112 formed in a package structure 111 and an optical chip 113 connected to the package structure 111, wherein one side of the optical chip 113 is connected to an optical fiber 14, and a shelf 15 is provided below a junction of the optical chip 113 and the optical fiber 14, so that optical signals can be transmitted to the optoelectronic module 11 for communication. At the same time, a switch chip 12 (switch integrated circuit or switch IC) must be mounted on the circuit board 10 to be used in a terminal product, wherein the switch chip 12 is firstly disposed on a substrate 13, and then is mounted on the circuit board 10 via the substrate 13.

However, in the aforementioned co-packaged optical device, the semiconductor chip is embedded in the package structure. The electrical connection between the semiconductor chip and the optical chip must be via multiple circuit layers, and the electrical connection between the optoelectronic module and the switch chip must be via the substrate and the circuit board. Therefore, for future high-speed computing and data-intensive applications that require the transmission of large amounts of information, there will be information delays, and the transmission of signals over long lines will generate a large amount of heat, which is caused by poor transmission efficiency. In addition, the optical chip and the switch chip must transmit signals via the circuit board and the circuit inside the substrate. Not only is the overall size of the device too large and too thick, which is not conducive to the miniaturization of electronic products, but its signal transmission path is too long, which can easily lead to signal loss and cause problems in the application of terminal products. In addition, there is a risk that the shelf is suspended in the air, thereby resulting in insufficient support for the optical fiber and a risk of breakage.

Therefore, how to overcome the above-mentioned drawbacks of the prior art has become an urgent issue to be solved.

### SUMMARY

In view of the above-mentioned deficiencies of the prior art, the present disclosure provides an optical package structure, which comprises: a substrate; at least one optical element having an active surface and an inactive surface opposite to the active surface, wherein the inactive surface is disposed on the substrate; an interposer having a first surface, a second surface opposite to the first surface, and a plurality of conductive vias connecting the first surface and the second surface, wherein the second surface is disposed on the substrate and the active surface of the optical element, and the substrate and the optical element are electrically connected to the plurality of conductive vias; an electronic element disposed on the first surface of the interposer and electrically connected to the plurality of conductive vias; and at least one semiconductor element disposed on the first surface of the interposer and electrically connected to the plurality of conductive vias.

The present disclosure further provides a method of manufacturing an optical package structure, and the method comprises: disposing an inactive surface of at least one optical element having an active surface and the inactive surface opposite to the active surface on a substrate; providing an interposer having a first surface, a second surface opposite to the first surface, and a plurality of conductive vias connecting the first surface and the second surface; disposing an electronic element and at least one semiconductor element on the first surface of the interposer, wherein the electronic element and the semiconductor element are electrically connected to the plurality of conductive vias; and disposing the second surface of the interposer on the substrate and the active surface of the optical element, wherein the substrate and the optical element are electrically connected to the plurality of conductive vias.

In the aforementioned optical package structure and method, the present disclosure further comprises an optical accessory disposed on the active surface of the optical element.

In the aforementioned optical package structure and method, the interposer is connected to the substrate and the active surface of the optical element via a plurality of conductive elements.

In the aforementioned optical package structure and method, the present disclosure further comprises a filling layer formed between the interposer and the substrate.

In the aforementioned optical package structure and method, the present disclosure further comprises a packaging layer formed on the substrate and encapsulating the optical element, the interposer, the electronic element, and the semiconductor element.

In the aforementioned optical package structure and method, the electronic element is a switch application-specific integrated circuit.

In the aforementioned optical package structure and method, the semiconductor element is an electronic integrated circuit element.

In the aforementioned optical package structure and method, the optical element is a photonic integrated circuit element or an optical module.

As can be seen from the above, in the optical package structure and the manufacturing method thereof of the present disclosure, the optical elements and the semiconductor elements are respectively disposed on the upper and lower sides of the interposer to achieve the shortest transmission distance via the conductive vias, wherein the inactive surface of each of the optical elements is made to abut against the upper surface of the substrate. This allows the optical accessories to be more stable when connected to the optical elements, so that the optical accessories will not be damaged when connected to the optical fibers. In addition, the optical elements and the semiconductor elements can be electrically connected to the electronic element via the conductive vias of the interposer, without having to go through the substrate and the circuit board as in the conventional structure, thereby improving the transmission efficiency.

### BRIEF DESCRIPTION OF THE DRAWINGS

FIG. 1 is a cross-sectional schematic view of a conventional co-packaged optical device.

FIG. 2A to FIG. 2D are cross-sectional schematic views illustrating a method of manufacturing an optical package structure according to the present disclosure.

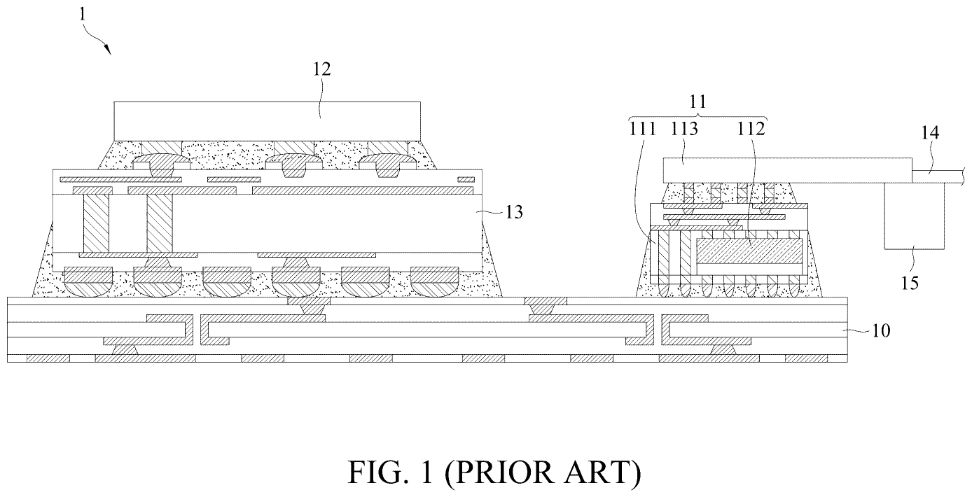

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “third,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

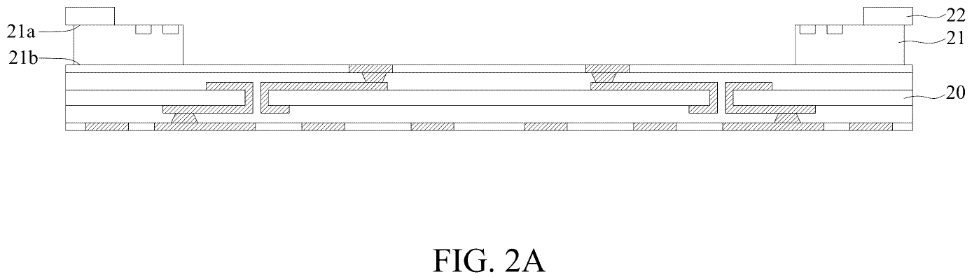

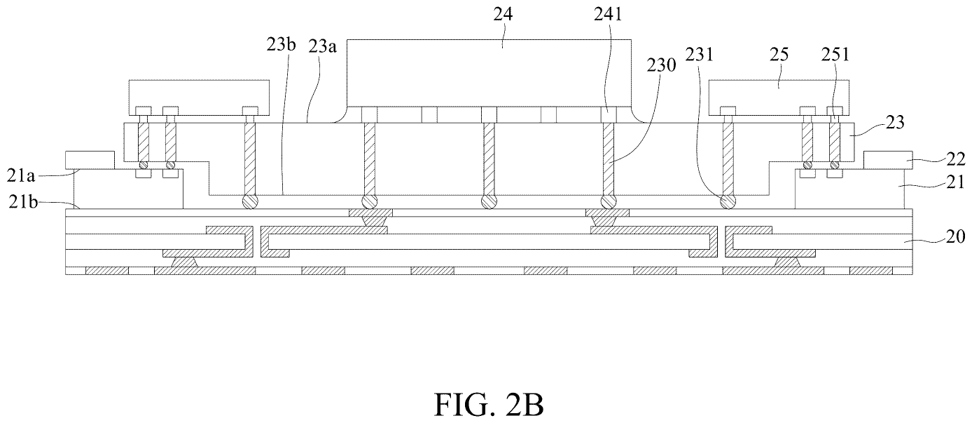

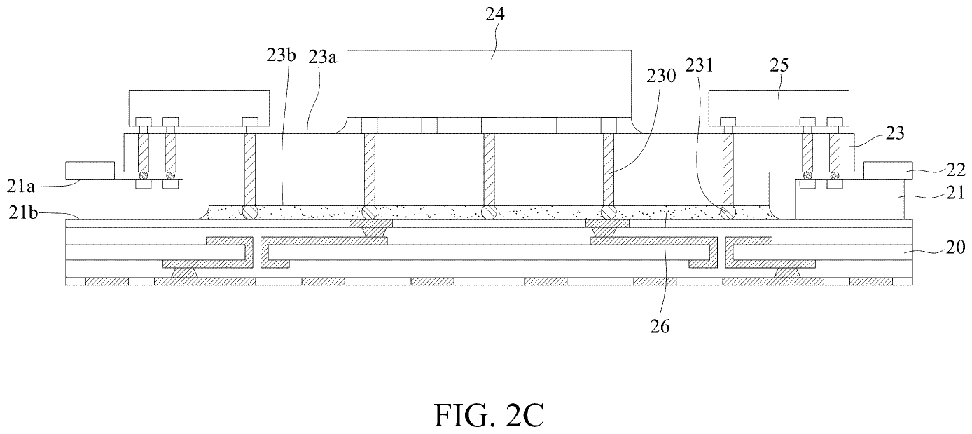

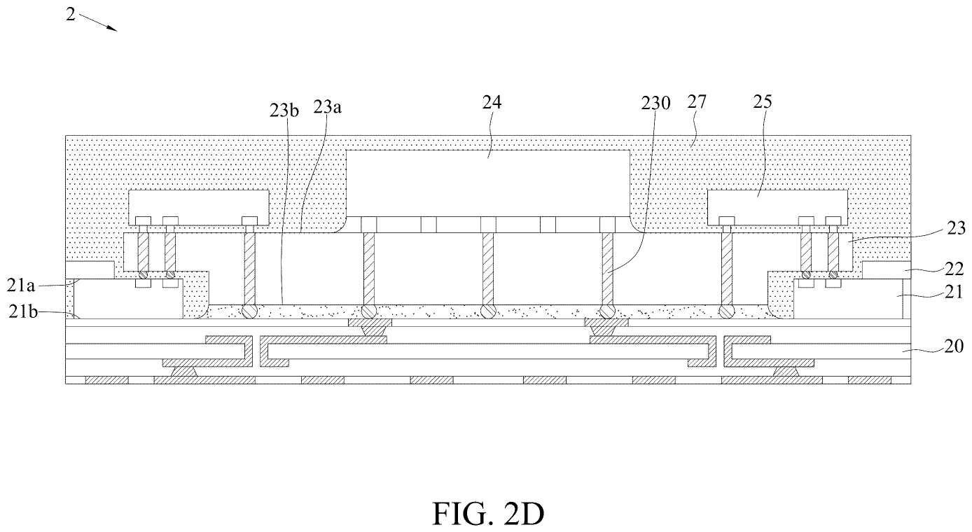

Please refer to FIG. 2A to FIG. 2D, which are cross-sectional schematic views illustrating a method of manufacturing an optical package structure 2 according to the present disclosure.

As shown in FIG. 2A, a substrate 20 is provided, and at least one optical element 21 is disposed on the substrate 20. The diagram of this embodiment shows that a plurality of optical elements 21 are disposed on the substrate 20.

In one embodiment, the substrate 20 has at least one insulating layer and at least one circuit layer bonded to the insulating layer. The insulating layer is made of, for example, a dielectric material such as polybenzoxazole (PBO), polyimide (PI), prepreg (PP), or the like. The circuit layer is, for example, a fan-out type redistribution layer, and the circuit layer is made of, for example, copper metal.

Each of the optical elements 21 has an active surface 21a and an inactive surface 21b opposite to the active surface 21a, and the inactive surface 21b is disposed on the substrate 20. Each of the optical elements 21 is, for example, a photonic integrated circuit (PIC) element or an optical module, wherein the optical module may include a photonic integrated circuit element, a total internal reflection mirror (total internal reflection glass or TIR glass), and/or other optical components.

In addition, an optical accessory 22 may be disposed on the active surface 21a of each of the optical elements 21, such as an optical fiber module, an optical fiber slot, an optical fiber array unit, or a waveguide array, wherein the optical accessory 22 may be supported by the substrate 20 (and the optical element 21).

In another embodiment, the optical accessory 22 can be integrated into the optical element 21.

As shown in FIG. 2B, an interposer 23 is provided. The interposer 23 has a first surface 23a, a second surface 23b opposite to the first surface 23a, and a plurality of conductive vias 230 (such as conductive through-silicon vias) connecting the first surface 23a and the second surface 23b. At least one electronic element 24 and at least one semiconductor element 25 are disposed on the first surface 23a of the interposer 23. In the diagram of this embodiment, an electronic element 24 and a plurality of semiconductor elements 25 are disposed on the first surface 23a of the interposer 23, wherein the plurality of semiconductor elements 25 are disposed around the electronic element 24.

Then, the interposer 23 provided with the electronic element 24 and the semiconductor elements 25 is placed on the substrate 20 and the active surface 21a of each of the optical elements 21 via the second surface 23b of the interposer 23, and the interposer 23 is electrically connected to the substrate 20 and the optical elements 21.

The electronic element 24 is, for example, a switch application-specific integrated circuit (switch ASIC). The electronic element 24 is electrically connected to the plurality of conductive vias 230 of the interposer 23 via a plurality of conductive elements 241 such as solder bumps or copper bumps.

Each of the semiconductor elements 25 is, for example, an electronic integrated circuit (EIC) element. The semiconductor elements 25 are electrically connected to the plurality of conductive vias 230 of the interposer 23 via a plurality of conductive elements 251 such as solder bumps or copper bumps.

The interposer 23 is connected to the substrate 20 and the active surfaces 21a of the optical elements 21 via a plurality of conductive elements 231 such as solder bumps or copper bumps. The substrate 20 and the optical elements 21 are electrically connected to the plurality of conductive vias 230 of the interposer 23.

Compared with conventional optical chips and switch chips that must transmit signals via circuit boards and circuits inside substrates and require a line width of at least 10 microns, the line width of the interposer 23 of the present disclosure as the main transmission path can be shortened to 5 microns, thereby achieving dense transmission lines and shortening the space required for transmission. Furthermore, the optical elements 21, the semiconductor elements 25, and the electronic element 24 can be electrically connected to each other via the plurality of conductive vias 230 of the interposer 23 to optimize the transmission distance. Multi-party integration achieves advantages such as increased transmission rate and space utilization.

In another embodiment, the interposer 23 may be first placed on the substrate 20 and the optical elements 21, and then the electronic element 24 and the semiconductor elements 25 may be placed on the interposer 23.

As shown in FIG. 2C, a filling layer 26 (e.g., underfill) may be optionally formed between the interposer 23 and the substrate 20 to encapsulate the plurality of conductive elements 231 used for electrically connecting the interposer 23 and the substrate 20.

As shown in FIG. 2D, a packaging layer 27 is formed on the substrate 20, so that the packaging layer 27 encapsulates the optical elements 21, the interposer 23, the electronic element 24, and the semiconductor elements 25. The optical accessories 22 are exposed from the packaging layer 27 for subsequent connection with optical fibers. Accordingly, the transmission path of the optical signal can be sequentially passed through the optical element 21, the interposer 23 (the plurality of conductive vias 230) to the semiconductor element 25 from the optical accessory 22, and sequentially passed through the optical element 21, the interposer 23 (the plurality of conductive vias 230) to the electronic element 24 and the substrate 20, thereby effectively improving the transmission rate.

Through the above-mentioned manufacturing method, the present disclosure further discloses an optical package structure 2, which comprises: a substrate 20, optical elements 21 disposed on the substrate 20, an interposer 23 disposed on the substrate 20 and the optical elements 21, and an electronic element 24 and semiconductor elements 25 disposed on the interposer 23.

Each of the optical elements 21 has an active surface 21a and an inactive surface 21b opposite to the active surface 21a, wherein the inactive surface 21b is disposed on the substrate 20, and an optical accessory 22 is disposed on the active surface 21a. Each of the optical elements 21 is, for example, a photonic integrated circuit element or an optical module.

The interposer 23 has a first surface 23a, a second surface 23b opposite to the first surface 23a, and a plurality of conductive vias 230 connecting the first surface 23a and the second surface 23b, so that the second surface 23b of the interposer 23 is placed on the substrate 20 and the active surface 21a of each of the optical elements 21, and the plurality of conductive vias 230 of the interposer 23 are electrically connected to the substrate 20 and each of the optical elements 21.

The electronic element 24 is, for example, a switch application-specific integrated circuit, which is disposed on the first surface 23a of the interposer 23 and is electrically connected to the plurality of conductive vias 230.

Each of the semiconductor elements 25 is, for example, an electronic integrated circuit element, which is placed on the first surface 23a of the interposer 23 and is electrically connected to the plurality of conductive vias 230.

To sum up, in the optical package structure and the manufacturing method thereof of the present disclosure, the optical elements and the semiconductor elements are respectively disposed on the upper and lower sides of the interposer to achieve the shortest transmission distance via the conductive vias, wherein the inactive surface of each of the optical elements is made to abut against the upper surface of the substrate. This allows the optical accessories (optical fiber modules) to be more stable when connected to the optical elements, so that the optical accessories will not be damaged when connected to the optical fibers. In addition, the optical elements and the semiconductor elements can be electrically connected to the electronic element via the conductive vias of the interposer, without having to go through the substrate and the circuit board as in the conventional structure, thereby improving the transmission efficiency. Furthermore, the optical package structure has high feasibility and can be manufactured using existing semiconductor packaging processes without the need to develop special processes or purchase special equipment, thereby reducing product costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An optical package structure, comprising:
a substrate;
at least one optical element having an active surface and an inactive surface opposite to the active surface, wherein the inactive surface is disposed on the substrate;
an interposer having a first surface, a second surface opposite to the first surface, and a plurality of conductive vias connecting the first surface and the second surface, wherein the second surface is disposed on the substrate and the active surface of the optical element, and the substrate and the optical element are electrically connected to the plurality of conductive vias;
an electronic element disposed on the first surface of the interposer and electrically connected to the plurality of conductive vias; and
at least one semiconductor element disposed on the first surface of the interposer and electrically connected to the plurality of conductive vias.

2. The optical package structure of claim 1, further comprising: an optical accessory disposed on the active surface of the optical element.

3. The optical package structure of claim 1, wherein the interposer is connected to the substrate and the active surface of the optical element via a plurality of conductive elements.

4. The optical package structure of claim 1, further comprising: a filling layer formed between the interposer and the substrate.

5. The optical package structure of claim 1, further comprising: a packaging layer formed on the substrate and encapsulating the optical element, the interposer, the electronic element, and the semiconductor element.

6. The optical package structure of claim 1, wherein the electronic element is a switch application-specific integrated circuit.

7. The optical package structure of claim 1, wherein the semiconductor element is an electronic integrated circuit element.

8. The optical package structure of claim 1, wherein the optical element is a photonic integrated circuit element or an optical module.

9. A method of manufacturing an optical package structure, comprising:
disposing an inactive surface of at least one optical element having an active surface and the inactive surface opposite to the active surface on a substrate;
providing an interposer having a first surface, a second surface opposite to the first surface, and a plurality of conductive vias connecting the first surface and the second surface;
disposing an electronic element and at least one semiconductor element on the first surface of the interposer, wherein the electronic element and the semiconductor element are electrically connected to the plurality of conductive vias; and
disposing the second surface of the interposer on the substrate and the active surface of the optical element, wherein the substrate and the optical element are electrically connected to the plurality of conductive vias.

10. The method of claim 9, further comprising: disposing an optical accessory on the active surface of the optical element.

11. The method of claim 9, wherein the interposer is connected to the substrate and the active surface of the optical element via a plurality of conductive elements.

12. The method of claim 9, further comprising: forming a filling layer between the interposer and the substrate.

13. The method of claim 9, further comprising: forming a packaging layer on the substrate to encapsulate the optical element, the interposer, the electronic element, and the semiconductor element.

14. The method of claim 9, wherein the electronic element is a switch application-specific integrated circuit.

15. The method of claim 9, wherein the semiconductor element is an electronic integrated circuit element.

16. The method of claim 9, wherein the optical element is a photonic integrated circuit element or an optical module.
